(19) United States
(12) Patent Application Publication
(10) Pub. No.: US 2026/0262524 A1
(43) Pub. Date: Sep. 3, 2026

(54) SEMICONDUCTOR DEVICE

(71) Applicant: Renesas Electronics Corporation, Tokyo (JP)

(72) Inventors: Shinji TOJO, Tokyo (JP); Tatsuya KOBAYASHI, Tokyo (JP)

(21) Appl. No.: 19/552,609

(22) Filed: Feb. 27, 2026

(30) Foreign Application Priority Data
Feb. 28, 2025 (JP) 2025-032200

(51) Int. Cl. H10W 70/655; H10W 70/652; H10W 72/00; H10W 90/00

(52) U.S. Cl. CPC H10W 70/655; H10W 70/6528; H10W 72/884; H10W 90/734; H10W 90/754

(57) ABSTRACT

A plurality of conductive patterns formed in a wiring layer of a wiring substrate of a semiconductor device includes: a plurality of bonding fingers which is respectively arranged outside a chip mounting region, and which is arranged in a Y direction; and a plurality of wirings which is respectively connected to a plurality of first bonding fingers of the plurality of bonding fingers. The plurality of conductive patterns includes a fixed potential pattern arranged between adjacent two wirings of the plurality of wirings in a first region, and connected to a transmission path for a fixed potential. The fixed potential pattern arranged between the adjacent two wirings and the plurality of wirings extend so as to across the outer edge of the chip mounting region in a X direction crossing the Y direction.

### CROSS-REFERENCE TO RELATED APPLICATIONS

The disclosure of Japanese Patent Application No. 2025-032200 filed on Feb. 28, 2025, including the specification, drawings and abstract is incorporated herein by reference in its entirety.

### BACKGROUND

The present invention relates to a semiconductor device.

There are disclosed techniques listed below.

[Patent Document 1] Japanese Unexamined Patent Application Publication No. 2002-190488

There is technology for electrically connecting a semiconductor chip mounted on a wiring substrate and the wiring substrate via multiple wires (see, for example, Patent Document 1). Patent Document 1 discloses a dummy conductor pattern is arranged in areas where conductive patterns for wiring are not arranged on the main surface of the wiring substrate.

### SUMMARY

When mounting a semiconductor chip on a wiring substrate, an adhesive material is interposed between the wiring substrate and the semiconductor chip. However, if the flatness of the chip mounting region on the upper surface of the wiring substrate is low, voids (gaps) may occur between the adhesive material and the wiring substrate. The voids can cause the adhesive material and the wiring substrate to separate. Therefore, from the perspective of improving the reliability of semiconductor devices, technology to suppress the occurrence of the voids is necessary.

Other objects and novel features will become apparent from the description of this specification and the accompanying drawings.

A semiconductor device according to one embodiment includes: a semiconductor chip; a wiring substrate on which the semiconductor chip is mounted; and a film shaped adhesive material arranged between the semiconductor chip and the wiring substrate, and attached to each of the semiconductor chip and the wiring substrate. The wiring substrate includes: a first wiring layer in which a plurality of first conductive patterns is formed; and a first insulating layer covering the first wiring layer and having a third surface. The plurality of first conductive patterns includes a plurality of bonding fingers which is respectively arranged outside a chip mounting region. The plurality of first conductive patterns includes a plurality of first wirings which is arranged in a first region including a portion of an outer edge of the chip mounting region, and which is respectively connected to a plurality of first bonding fingers of the plurality of bonding fingers. The plurality of first conductive patterns includes a fixed potential pattern arranged between adjacent two first wirings of the plurality of first wirings in the first region, and connected to a transmission path for a fixed potential. The plurality of first bonding fingers is arranged in a first direction. The fixed potential pattern arranged between the adjacent two wirings and the plurality of first wirings extend so as to across the outer edge of the chip mounting region in a second direction crossing the first direction.

A semiconductor device according to another embodiment includes: a semiconductor chip; a wiring substrate on which the semiconductor chip is mounted; and a film shaped adhesive material arranged between the semiconductor chip and the wiring substrate, and attached to each of the semiconductor chip and the wiring substrate. The wiring substrate includes: a first wiring layer in which a plurality of first conductive patterns is formed; and a first insulating layer covering the first wiring layer and having a third surface. The plurality of first conductive patterns includes a plurality of bonding fingers which is respectively arranged outside a chip mounting region. The plurality of first conductive patterns includes a plurality of first wirings which is arranged in a first region including a portion of an outer edge of the chip mounting region, and which is respectively connected to a plurality of first bonding fingers of the plurality of bonding fingers. The plurality of first bonding fingers is arranged in a first direction. A width of each of the plurality of first wirings is larger than a distance between the plurality of first wirings. Each of the plurality of first wirings extends so as to across the outer edge of the chip mounting region in a second direction crossing the first direction.

According to the above embodiment, the performance of the semiconductor device can be improved.

### BRIEF DESCRIPTION OF THE DRAWINGS

FIG. 1 is a perspective view of a semiconductor device according to one embodiment.

FIG. 2 is a bottom view of the semiconductor device shown in FIG. 1.

FIG. 3 is a plan view showing a state where the sealing body shown in FIG. 1 is removed.

FIG. 4 is a cross-sectional view taken along line A-A of FIG. 1.

FIG. 5 is an enlarged plan view of the B part of the wiring substrate shown in FIG. 3.

FIG. 6 is an enlarged cross-sectional view along line C-C of FIG. 5.

FIG. 7 is an enlarged plan view showing the layout of the top wiring layer of the wiring substrate as an examined example for FIG. 5.

FIG. 8 is an enlarged cross-sectional view along line D-D of FIG. 7.

FIG. 9 is an enlarged plan view of the wiring substrate as a modified example for FIG. 5.

FIG. 10 is an enlarged cross-sectional view along line E-E of FIG. 9.

FIG. 11 is an explanatory diagram showing an example of the manufacturing process of the semiconductor device shown in FIG. 1.

FIG. 12 is a cross-sectional view of the semiconductor chip prepared in the semiconductor chip preparation process of FIG. 11.

FIG. 13 is a plan view showing an example of the wiring substrate prepared in the wiring substrate preparation process of FIG. 11.

### DETAILED DESCRIPTION

### Explanation of Description Format, Basic Term, And Usage in The Present Application

In the present application, the description of embodiments is divided into multiple sections for convenience. These are not mutually independent and separate, but one is a part detail of the other, or one is a modified example of the other. In principle, descriptions of similar parts are omitted. Also, each component in the embodiment is not essential unless clearly indicated as essential, theoretically limited in number, or obviously essential from the context.

Similarly, in the description of embodiments, materials, compositions, etc., even if it is stated as "X consisting of A", unless clearly limited or obviously limited from the context, elements other than A are not excluded. For example, regarding components, it means "X containing A as a main component". For example, even if it is stated as "silicon member", it is not limited to pure silicon but also includes SiGe (silicon-germanium) alloys and other multi-component alloys with silicon as the main component, and other additives. Also, even if it is stated as gold plating, Cu layer, nickel plating, etc., unless specifically indicated otherwise, it includes not only pure ones but also members with gold, Cu, nickel, etc. as the main component.

Furthermore, when referring to specific numbers or quantities, unless clearly limited or obviously limited from the context, the specific numbers are described as examples.

In the drawings of the embodiments, the same or similar parts are denoted by the same or similar symbols or reference numerals, and the description will not be repeated in principle.

In addition, in the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. Furthermore, even if it is not a cross-section, hatching or dot patterns may be applied to clearly indicate that it is not a gap or to clearly indicate the boundary of a region.

### Semiconductor Device

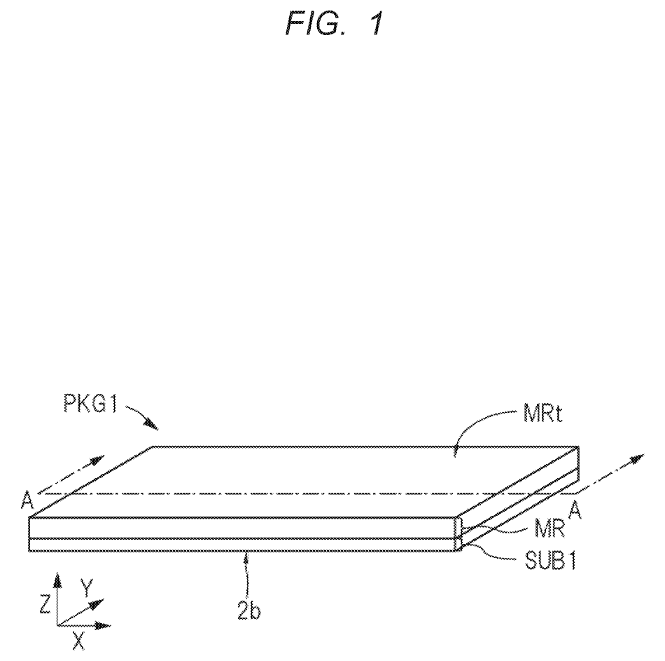

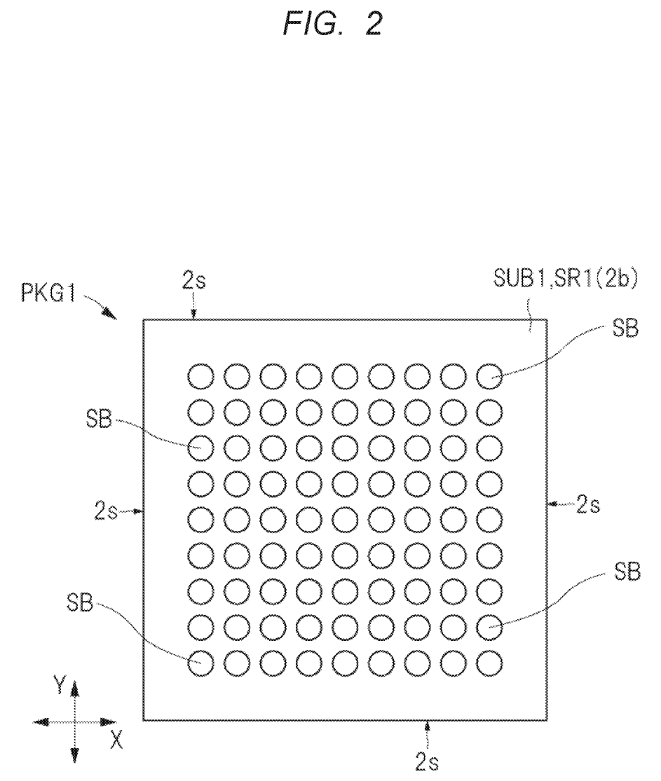

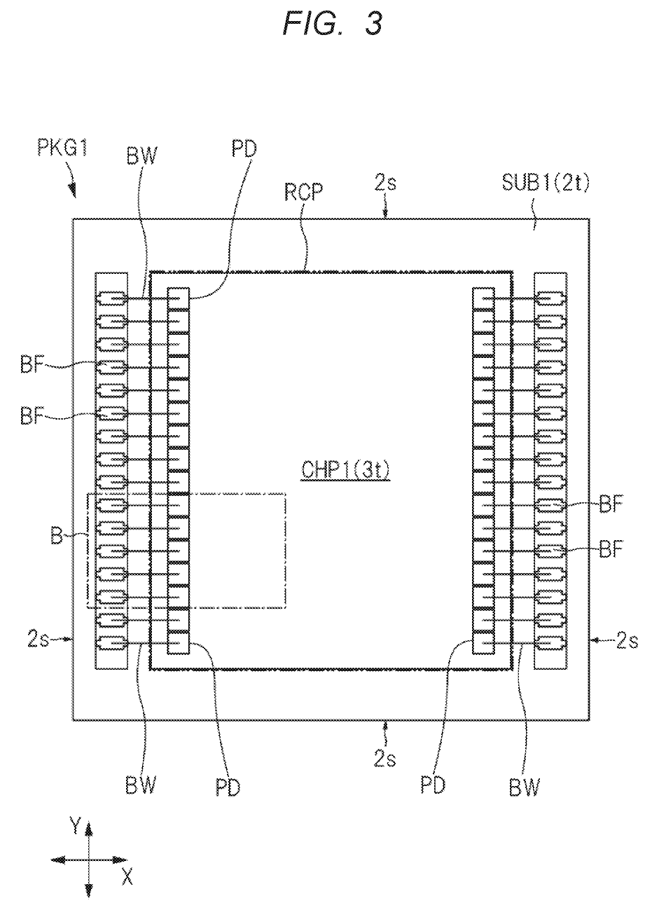

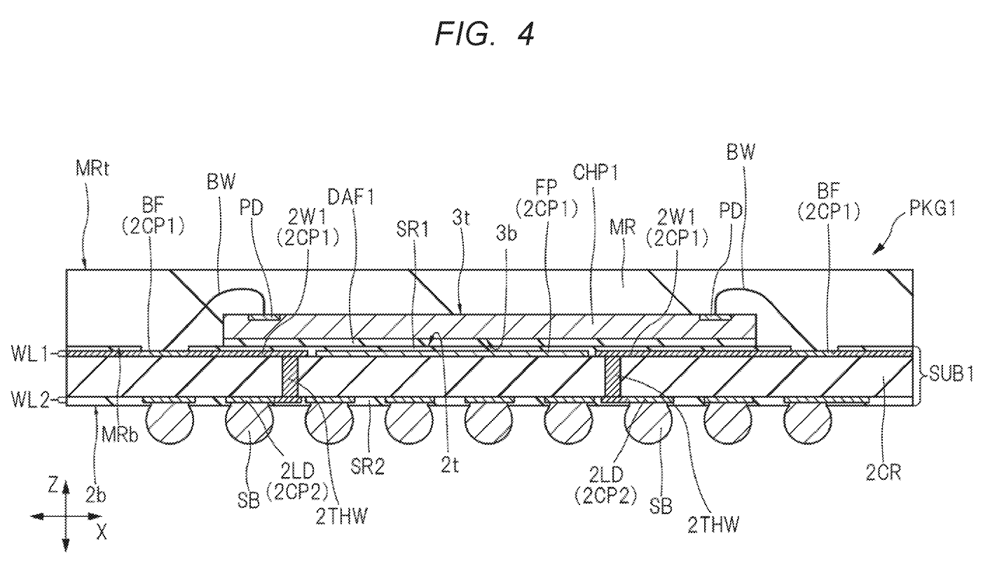

First, the semiconductor device of the present embodiment will be described. FIG. 1 is a perspective view of a semiconductor device according to one embodiment. FIG. 2 is a bottom view of the semiconductor device shown in FIG. 1. Also, FIG. 3 is a plan view showing a state where the sealing body shown in FIG. 1 is removed. Also, FIG. 4 is a cross-sectional view along line A-A of FIG. 1.

FIGS. 1 to 4 describe either the X direction (see FIGS. 1 to 4), the Y direction (see FIGS. 1, 2, and 3), or the Z direction (see FIGS. 1 and 4). The Y direction is a direction intersecting the X direction, and in the following description, the X direction and Y direction are perpendicular to each other. The Z direction is a direction perpendicular to each of the X direction and Y direction. In other words, the Z direction is the normal direction to the X-Y plane including the X direction and Y direction (in other words, the vertical direction). In the following description, "thickness" means the length in the Z direction in principle. Also, in the following description, "plan view" means a plan view seen from the X-Y plane in principle.

The semiconductor device PKG1 of the present embodiment includes a wiring substrate SUB1 and a semiconductor chip CHP1 mounted on the wiring substrate SUB1 (see FIG. 3).

Also, as shown in FIG. 4, the semiconductor device PKG1 has a film shaped adhesive material DAF1 adhered to the semiconductor chip CHP1 and the wiring substrate SUB1. The adhesive material DAF1 is arranged between the lower surface 3b of the semiconductor chip CHP1 and the upper surface 2t of the wiring substrate SUB1.

Also, the semiconductor device PKG1 has multiple wires BW connected to each of the semiconductor chip CHP1 and the wiring substrate SUB1.

Also, the semiconductor device PKG1 has a sealing body MR that seals the semiconductor chip CHP1 and multiple wires BW. The sealing body MR is formed to cover the upper surface 2t of the wiring substrate SUB1.

As shown in FIG. 4, the semiconductor chip CHP1 mounted on the wiring substrate SUB1 has an upper surface (main surface, front surface) 3t and a lower surface (main surface, back surface) 3b opposite to the upper surface 3t.

Also, as shown in FIG. 3, the semiconductor chip CHP1 forms a rectangle in plan view. As shown in FIG. 3, the semiconductor chip CHP1 is mounted on the wiring substrate SUB1 such that each side of the upper surface 3t of the semiconductor chip CHP1 aligns with each side constituting the outer edge of the upper surface 2t of the wiring substrate SUB1.

On the upper surface 3t of the semiconductor chip CHP1, multiple pads (electrode pads) PD are arranged. The multiple pads PD are input/output terminals of the semiconductor chip CHP1, exposed from the protective film (passivation film) in the openings formed in the protective film on the upper surface 3t of the semiconductor chip CHP1.

In the example shown in FIG. 3, multiple pads PD are arranged along two sides extending in the Y direction out of the four sides of the semiconductor chip CHP1. However, the layout of the pads PD has various modifications in addition to the embodiment shown in FIG. 3. For example, there may be cases where pads PD are arranged along each of the four sides of the semiconductor chip CHP1. Additionally, each of the multiple pads PD is mainly composed of aluminum (Al), for example.

As shown in FIGS. 3 and 4, the semiconductor chip CHP1 is mounted on the upper surface 2t of the wiring substrate SUB1. In the example shown in FIG. 3, the semiconductor chip CHP1 is mounted at the center of the upper surface 2t of the wiring substrate SUB1. In the following description, the area of the upper surface 2t of the wiring substrate SUB1 where the semiconductor chip CHP1 is mounted, or the area where the semiconductor chip CHP1 is to be mounted, is referred to as the chip mounting region.

As shown in FIG. 4, the semiconductor chip CHP1 is mounted on the wiring substrate SUB1 with the lower surface 3b facing the upper surface 2t of the wiring substrate SUB1 via an adhesive material DAF1. In other words, the semiconductor chip CHP1 is mounted using a so-called face-up mounting method, where the opposite surface (lower surface 3b) of the upper surface 3t, on which multiple pads PD are formed, faces the chip mounting surface (upper surface 2t).

The adhesive material DAF1 is an adhesive material that bonds and fixes the semiconductor chip CHP1 to the wiring substrate SUB1, and is, for example, a resin film called DAF (Die Attach Film). Details will be described later, but the adhesive material DAF1 is used in a state where it is pre-attached to the lower surface 3b of the semiconductor chip CHP1 during the die bonding process. Generally, a paste-like adhesive applied on the wiring substrate may be used as a die bonding material for mounting a semiconductor chip on the wiring substrate. The adhesive material DAF1 is distinguished from the aforementioned paste-like adhesive.

As shown in FIG. 4, the wiring substrate SUB1 has an upper surface (surface, main surface, chip mounting surface) 2t on which the semiconductor chip CHP1 is mounted, and a lower surface (surface, main surface, mounting surface) 2b opposite to the upper surface 2t. Additionally, each of the upper surface 2t and the lower surface 2b of the wiring substrate SUB1 has multiple sides 2s at the outer edge (see FIGS. 2 and 3). In the present embodiment, the upper surface 2t (see FIG. 3) and the lower surface 2b (see FIG. 2) of the wiring substrate SUB1 are each rectangular. As shown in FIG. 4, the upper surface 2t of the wiring substrate SUB1 is the chip mounting surface facing the lower surface 3b of the semiconductor chip CHP1.

The wiring substrate SUB1 includes a wiring layer WL1 in which multiple conductive patterns 2CP1 are formed, and an insulating layer SR1 that covers the wiring layer WL1 and has the upper surface 2t. Additionally, the wiring substrate SUB1 includes a wiring layer WL2 in which multiple conductive patterns 2CP2 are formed, and an insulating layer SR2 that covers the wiring layer WL2 and has the lower surface 2b.

The wiring layer WL1 is the wiring layer positioned closest to the upper surface 2t among the multiple wiring layers of the wiring substrate SUB1. The wiring layer WL2 is the wiring layer positioned closest to the lower surface 2b among the multiple wiring layers of the wiring substrate SUB1. In the example shown in FIG. 4, the wiring substrate SUB1 is a two-layer structure wiring substrate consisting of the wiring layers WL1 and WL2.

Each of the wiring layers WL1 and WL2 is formed on a core insulating layer (insulating layer) 2CR. The core insulating layer 2CR is made of, for example, a prepreg impregnated with resin in glass fibers. In the core insulating layer 2CR, multiple through-hole wirings (via wirings) 2THW, which are interlayer conductive paths, are formed. The through-hole wiring 2THW is a conductor pattern that penetrates the core insulating layer 2CR in the thickness direction. The wiring layers WL1 and WL2 are electrically connected via the through-hole wiring 2THW.

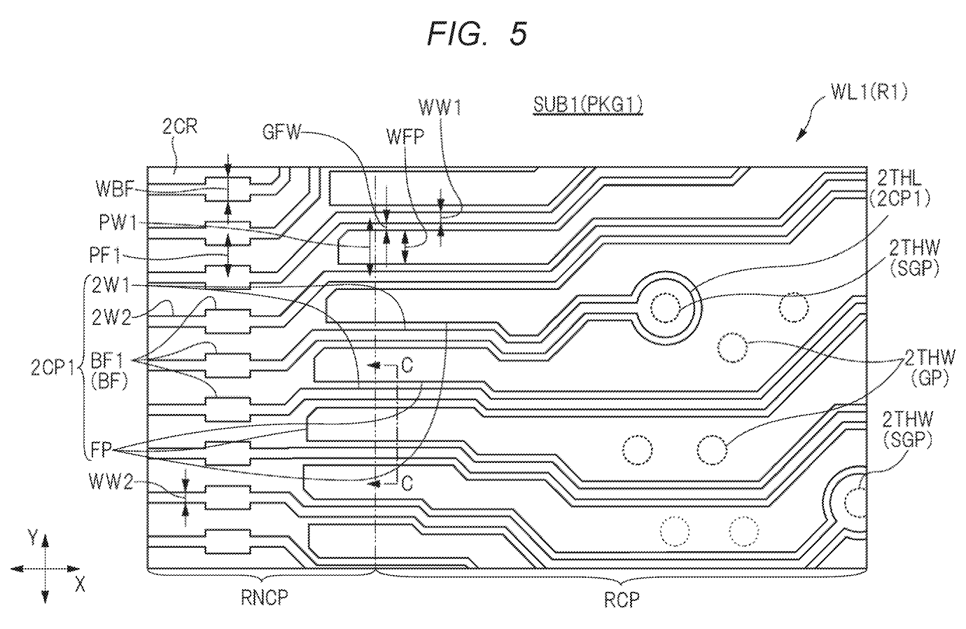

In the present embodiment, the interlayer conductive path penetrating the core insulating layer 2CR is described as the through-hole wiring 2THW. However, in the following description, the interlayer conductive path described as the through-hole wiring 2THW can be interpreted as via wiring. Similarly, in the following description, the conductor pattern described as the through-hole land 2THL (see FIG. 5 described later) can be interpreted as via land.

The multiple conductive patterns 2CP1 of the topmost wiring layer WL1 of the wiring substrate SUB1 include bonding fingers (terminals, chip mounting surface side terminals) BF, wiring 2W1, and fixed potential patterns (conductor planes, large area patterns) FP.

Most of the multiple conductive patterns 2CP1 are covered by the insulating layer SR1. However, as shown in FIGS. 3 and 4, each of the multiple bonding fingers BF is exposed from the insulating layer SR1 at the openings formed in the insulating layer SR1. One end portion of the wire BW is bonded to the exposed surface of the bonding finger BF. The other end portion of the wire BW is bonded to the pads PD arranged on the upper surface 3t of the semiconductor chip CHP1.

The portion of the wiring layer WL1 that overlaps with the chip mounting region RCP is entirely covered by the insulating layer SR1. Additionally, each of the multiple bonding fingers BF is exposed from the insulating layer SR1 at least in the portions where multiple wires BW are bonded.

The multiple conductive patterns 2CP2 of the bottommost wiring layer WL2 of the wiring substrate SUB1 include lands (terminals, mounting surface side terminals) 2LD. Each of the multiple conductive patterns 2CP1 and multiple conductive patterns 2CP2 is made of, for example, copper (Cu).

The wiring layer WL2 is covered by the insulating layer SR2. Each of the insulating layers SR1 and SR2 is a solder resist film. Multiple openings are formed in the insulating layer SR2, and the lands 2LD are exposed from the insulating layer SR2 at the openings. On the exposed surface of the land 2LD, a solder ball SB, which is a ball-shaped solder material, is connected.

The multiple pads PD of the semiconductor chip CHP1 and the multiple bonding fingers BF of the wiring substrate SUB1 are each electrically connected via multiple wires BW. The multiple wires BW are made of a metal mainly composed of, for example, gold (Au) or copper (Cu).

It should be noted that the number or layout of the multiple external terminals (solder balls SB) provided on the wiring substrate SUB1 has various modifications in addition to the embodiment shown in FIG. 2. Also, in FIG. 4, a two-layer structure wiring substrate SUB1 with wiring layers formed on both the upper and lower surfaces of the core insulating layer 2CR is illustratively shown, but the number of wiring layers is not limited to two and may include three or more wiring layers.

As shown in FIG. 4, the semiconductor chip CHP1 and the multiple wires BW are sealed by the sealing body MR. The sealing body MR has an upper surface MRt and a lower surface MRb located opposite to the upper surface MRt. As shown in FIG. 1, the sealing body MR forms a rectangle in plan view.

In the present embodiment, the entire upper surface 2t of the wiring substrate SUB1 shown in FIG. 3 is covered by the sealing body MR shown in FIG. 1. Therefore, the planar area of the sealing body MR (the area when viewed in plan from the upper surface MRt side) is the same as the planar area of the upper surface 2t of the wiring substrate SUB1 (see FIG. 3). Additionally, the side surface of the sealing body MR is continuous with the side surface of the wiring substrate SUB1.

### Details Around Chip Mounting Region

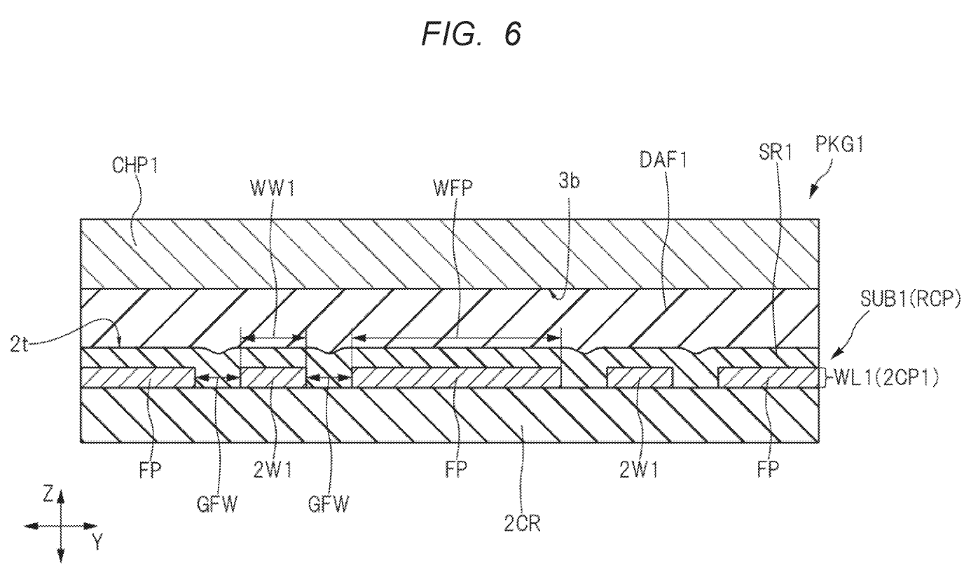

Next, the detailed structure around the chip mounting region RCP where the semiconductor chip CHP1 is mounted on the upper surface 2t of the wiring substrate SUB1 shown in FIG. 3 will be described. FIG. 5 is an enlarged plan view of the B portion of the wiring substrate shown in FIG. 3. In FIG. 5, the plane of the wiring layer WL1 is illustrated among the layers of the wiring substrate SUB1 shown in FIG. 4. In other words, FIG. 5 is a transparent plan view of the B portion of FIG. 3. Additionally, FIG. 5 illustrates the boundary line between the chip mounting region RCP and the surrounding area of the chip mounting region RCP shown in FIG. 3 (in other words, the outer edge of the chip mounting region RCP) with a two-dot chain line. FIG. 6 is an enlarged cross-sectional view along line C-C of FIG. 5.

In the following description, the area of the wiring layer WL1 of the wiring substrate SUB1, which is the area of the B portion of FIG. 3, that is, the area illustrated in FIG. 5, is defined and described as area R1. As shown in FIG. 5, in transparent plan view, area R1 includes a part of the chip mounting region RCP and a part of the area outside the chip mounting region RCP (area RNCP shown in FIG. 5). The area RNCP is an area adjacent to the chip mounting region RCP.

As shown in FIG. 5, the multiple conductive patterns 2CP1 include multiple bonding fingers BF, multiple wirings 2W1, and a fixed potential pattern FP. The multiple bonding fingers BF are arranged outside the chip mounting region RCP (area RNCP shown in FIG. 5).

In the example shown in FIG. 5, the multiple conductive patterns 2CP1 include wiring 2W2. The wiring 2W2 has one end portion connected to the bonding finger BF and extends in the direction opposite to the chip mounting region RCP. The wiring 2W2 is used as a power supply line when forming the bonding finger BF and wiring 2W1 by the electroplating method. However, as a modification, there may be cases where the wiring 2W1 shown in FIG. 5 is not formed.

The wiring 2W1 is arranged within area R1 in transparent plan view. One end portion of the wiring 2W1 is electrically connected to multiple bonding fingers BF1 arranged in area R1 among the multiple bonding fingers BF. The other end portion of wiring 2W1 is connected to the through-hole land (via land) 2THL, which is connected to the through-hole wiring 2THW shown in FIG. 4.

The fixed potential pattern FP is arranged between each of the multiple wirings 2W1 within the region R1 in a transparent plan view. In particular, at the boundary between the chip mounting region RCP and the outer region RNCP of the chip mounting region RCP, multiple wirings 2W1 and the fixed potential pattern FP are alternately arranged in the Y direction.

The fixed potential pattern FP is connected to the transmission path for the fixed potential. In the example shown in FIG. 5, the fixed potential pattern FP is connected to the ground path GP, which is the transmission path for the ground potential (reference potential). In other words, the fixed potential pattern FP is supplied with ground potential. Also, although not shown, the fixed potential pattern FP may be connected to the power path, which is the transmission path for the power supply potential. Furthermore, some of the multiple fixed potential patterns FP may be connected to the transmission path for the reference potential, while others may be connected to the supply path of the power supply potential.

The path supplying fixed potentials such as reference potential and power supply potential is preferably a large-area conductor pattern from the viewpoint of reducing potential fluctuations (in other words, noise). In the present embodiment, multiple fixed potential patterns FP are divided via wiring 2W1 at the boundary between the chip mounting region RCP and the outer region RNCP of the chip mounting region RCP. However, multiple fixed potential patterns FP are interconnected inside the chip mounting region RCP.

As shown in FIG. 5, multiple bonding fingers BF1 are arranged in the Y direction. Also, in a transparent plan view, the fixed potential pattern FP arranged between each of the multiple wirings 2W1 and the multiple wirings 2W1 extend in the X direction, which intersects the Y direction, so as to across the outer edge of the chip mounting region RCP.

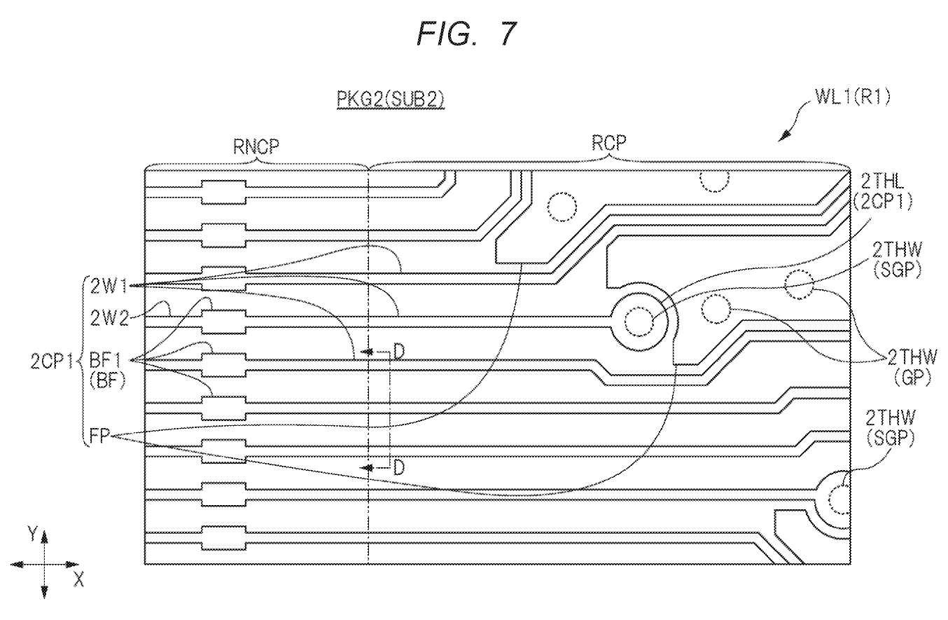

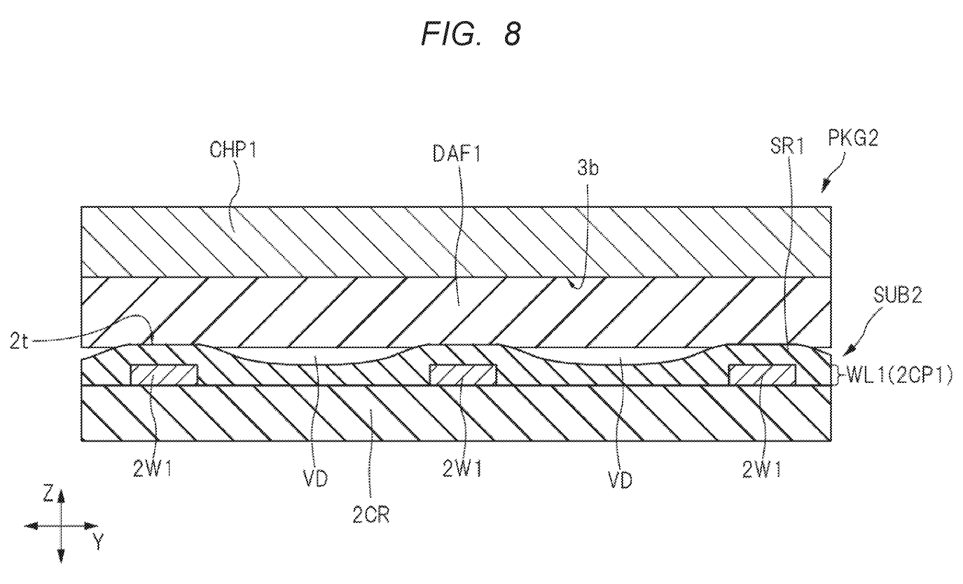

Here, a semiconductor device, which is an examined example for the present embodiment, will be described. FIG. 7 is an enlarged plan view showing the layout of the top wiring layer of the wiring substrate, which is an examined example for FIG. 5. FIG. 8 is an enlarged cross-sectional view along line D-D of FIG. 7.

The wiring substrate SUB2 provided in the semiconductor device PKG2 shown in FIGS. 7 and 8 has a layout of the wiring layer WL1 that differs from the wiring substrate SUB1 provided in the semiconductor device PKG1 shown in FIGS. 5 and 6. Specifically, in the case of wiring substrate SUB2, as shown in FIG. 7, multiple wirings 2W1 are adjacent to each other at the boundary between the chip mounting region RCP and the region RNCP. In other words, in the wiring layer WL1 of wiring substrate SUB2, the fixed potential pattern FP is not arranged between multiple wiring 2W1 at the boundary between the chip mounting region RCP and the region RNCP.

As shown in FIG. 8, the insulating layer SR1 covering the wiring layer WL1 is formed to cover the wiring layer WL1. Therefore, the upper surface of the insulating layer SR1 takes on a shape that follows the unevenness of the wiring layer WL1, which is the underlying layer. In other words, the flatness of the upper surface of the insulating layer SR1 depends on the flatness of the wiring layer WL1, which is the underlying layer.

Therefore, as shown in FIG. 8, in the region where multiple wirings 2W1 are densely arranged, many unevenness (depressions or grooves) is likely to be formed on the upper surface of the insulating layer SR1 covering the wirings 2W1 at a narrow pitch. The semiconductor device PKG2, similar to the semiconductor device PKG1 according to the present embodiment, uses a film shaped adhesive material DAF1 as a die bond material to adhesively fix the semiconductor chip CHP1 onto the wiring substrate SUB2.

The adhesive material DAF1, unlike paste-like adhesives, has low embedding performance against the unevenness of the adhesive surface. Therefore, as shown in FIG. 8, if many unevenness is formed at a narrow pitch on the upper surface of the insulating layer SR1, voids (gaps) VD may occur between the adhesive material DAF1 and the upper surface of the insulating layer SR1 (i.e., upper surface 2t) in some of the unevenness.

The void VD expands or contracts according to changes in the environmental temperature of the semiconductor device PKG2. When the void VD expands or contracts, stress is applied to the adhesive interface between the adhesive material DAF1 and the insulating layer SR1 each time. As a result, the adhesive material DAF1 and the insulating layer SR1 may peel off.

Also, when void VD occurs, the adhesive region decreases compared to when the entire surface of the adhesive material DAF1 is adhered to the insulating layer SR1. The strength of fixing the semiconductor chip CHP1 to the wiring substrate SUB2 is proportional to the adhesive area between the adhesive material DAF1 and the insulating layer SR1. Therefore, from the viewpoint of improving the reliability of the semiconductor device, it is necessary to suppress the occurrence of void VD.

As explained using FIG. 5, the fixed potential pattern FP arranged between each of the multiple wirings 2W1 and the multiple wirings 2W1 extend in the X direction so as to across the outer edge of the chip mounting region RCP. Therefore, at the boundary between the chip mounting region RCP and the region RNCP, the fixed potential pattern FP is arranged between the adjacent two wirings 2W1.

The separation distance between the adjacent two wirings 2W1 and the wiring width of wiring 2W1 are determined according to design specifications. Therefore, from the viewpoint of improving design flexibility, it is preferable that the separation distance between the adjacent two wirings 2W1 and the wiring width of wiring 2W1 can be arbitrarily set.

In the present embodiment, the fixed potential pattern FP is arranged between adjacent wirings 2W1 in the chip mounting region RCP. Therefore, by adjusting the width of the fixed potential pattern FP in the Y direction, the separation distance between wiring 2W1 and the fixed potential pattern FP can be controlled.

As shown in FIG. 6, even when using the film shaped adhesive material DAF1, if the height difference of the unevenness of the upper surface 2t is low, it is possible to adhere the entire lower surface of the adhesive material DAF1 to the insulating layer SR1. In the case of wiring substrate SUB1 shown in FIG. 6, the occupancy area ratio of the conductor pattern 2CP1 formed in the wiring layer WL1 in the chip mounting region RCP is higher than that of the wiring substrate SUB2 shown in FIG. 8. The reason for being able to increase the occupancy area ratio is that the fixed potential pattern FP is arranged between adjacent wirings 2W1.

Thus, according to the present embodiment, even when using adhesive material DAF1 as a die bond material to adhesively fix the semiconductor chip CHP1 to the wiring substrate SUB1, the occurrence of void VD as shown in FIG. 8 can be suppressed. As a result, the peeling between the adhesive material DAF1 and the insulating layer SR1 can be suppressed, thereby improving the reliability of the semiconductor device PKG1.

Next, the preferred relationships such as the separation distance or arrangement pitch of multiple conductive patterns 2CP1 formed in the wiring layer WL1 will be explained in order. In the following explanation, "arrangement pitch" refers to the distance between the centers of two target conductive patterns. "Separation distance" refers to the distance between two target conductive patterns, specifically the shortest distance. Also, "width" refers to the length in the direction perpendicular to the longitudinal direction.

First, in the example shown in FIG. 5, the arrangement pitch PW1 of each of the multiple wirings 2W1 at the position overlapping the outer edge of the chip mounting region RCP is larger than the arrangement pitch PF1 of each of the multiple bonding fingers BF1 in the Y direction. In other words, each of the multiple wirings 2W1 is arranged at a wider arrangement pitch PW1 than the arrangement pitch PF1 of the bonding fingers BF1 within the chip mounting region RCP.

The semiconductor device PKG1, as described above, has a structure in which the fixed potential pattern FP is arranged between adjacent wirings 2W1 within the chip mounting region RCP. Therefore, it is preferable that the arrangement pitch PW1 of adjacent wirings 2W1 is wide. This is because if the arrangement pitch PW1 of wiring 2W1 is narrow, it may not be possible to sufficiently secure the width of the fixed potential pattern FP in the Y direction of FIG. 5. If the arrangement pitch PW1 of adjacent wirings 2W1 is sufficiently wide, it is possible to widen the width of the fixed potential pattern FP. In this case, the patterning of the fixed potential pattern FP is easy. Alternatively, the processing accuracy of the separation distance GFW between the fixed potential pattern FP and wiring 2W1 can be improved.

On the other hand, multiple bonding fingers BF1 are arranged outside the chip mounting region RCP. Outside the chip mounting region RCP, the adhesive material DAF1 shown in FIG. 6 is not arranged. Therefore, in the region RNCP (see FIG. 5), even if depressions or grooves are formed on the upper surface 2t of the insulating layer SR1, the aforementioned issues do not occur. Therefore, the arrangement pitch PF1 of the bonding fingers BF1 is not particularly limited. Considering the arrangement efficiency of the bonding fingers BF1, a smaller arrangement pitch PF1 is preferable.

Also, as explained using FIG. 5, the fixed potential pattern FP arranged between each of the multiple wirings 2W1 and the multiple wirings 2W1 extend in the X direction so as to across the outer edge of the chip mounting region RCP. This allows the suppression of the occurrence of void VD (see FIG. 8) between the adhesive material DAF1 and the insulating layer SR1 in the peripheral region of the chip mounting region RCP.

Considering the above, it is preferable that the arrangement pitch PW1 of each of the multiple wirings 2W1 at the position overlapping the outer edge of the chip mounting region RCP is larger than the arrangement pitch PF1 of each of the multiple bonding fingers BF1 in the Y direction.

Next, in the example shown in FIG. 5, at the position overlapping the outer edge of the chip mounting region RCP, the separation distance GFW between each of the multiple wirings 2W1 and the fixed potential pattern FP is smaller than the width WFP of the fixed potential pattern FP in the Y direction.

As shown in FIG. 6, by reducing the value of the separation distance GFW, the depth of the recess formed on the upper surface 2t of the insulating layer SR1 can be reduced. However, if the value of the separation distance GFW is made extremely small, there may be a concern that the wiring 2W1 and the fixed potential pattern FP may short-circuit due to processing accuracy. Therefore, it is preferable that the value of the separation distance GFW be as small as possible within a permissible range from the viewpoint of processing accuracy.

On the other hand, as mentioned above, the fixed potential pattern FP is supplied with reference potential (e.g., ground potential) or power supply potential. Therefore, from the viewpoint of stabilizing the potential of the fixed potential pattern FP, it is preferable that the width WFP of the fixed potential pattern FP in the Y direction be large.

For the above reasons, at the position overlapping the outer edge of the chip mounting region RCP, it is preferable that the separation distance GFW between each of the multiple wirings 2W1 and the fixed potential pattern FP be smaller than the width WFP of the fixed potential pattern FP in the Y direction.

Next, in the example shown in FIG. 5, at the position overlapping the outer edge of the chip mounting region RCP, the separation distance GFW between each of the multiple wirings 2W1 and the fixed potential pattern FP is smaller than the width WW1 of the multiple wirings 2W1. If the width WW1 of the wiring 2W1 is small, the separation distance GFW may be the same value as the width WW1 of the wiring 2W1.

Each of the multiple wirings 2W1 is, for example, a part of a transmission path of electrical signals different from each other. In other words, each of the multiple wirings 2W1 is a transmission path for a signal (hereinafter called, signal transmission path SGP). The signal transmission path SGP is designed to prevent impedance discontinuities (in other words, to achieve characteristic impedance) in order to suppress losses due to signal reflection. For this reason, the wiring 2W1 constituting the signal transmission path SGP is formed to extend with a constant wiring width. Additionally, the wiring 2W1 is connected to a bonding finger BF1 to which a wire BW (see FIG. 3) is connected, or to a through-hole land 2THL to which a through-hole wiring 2THW is connected.

From the viewpoint of matching the impedance of the conductor pattern 2CP1, such as the bonding finger BF1 or the through-hole land 2THL, with the impedance of the wiring 2W1, the width WW1 of the wiring 2W1 tends to be small. For example, in the example shown in FIG. 5, the width WW1 of the multiple wirings 2W1 is smaller than the width WBF of the bonding finger BF1 in the Y direction.

In the example shown in FIG. 5, the separation distance GFW is smaller than the width WW1 of the wiring 2W1 constituting the signal transmission path. As already mentioned, by reducing the value of the separation distance GFW, the depth of the recess formed on the upper surface 2t of the insulating layer SR1 shown in FIG. 6 can be reduced.

Also, in the example shown in FIG. 5, the multiple conductive patterns 2CP1 include a wiring 2W2, which is a power supply line. The width WW2 of the wiring 2W2 is, for example, the same as the width WW1 of the wiring 2W1. Therefore, in the present embodiment, the separation distance GFW is smaller than the width WW2 of the wiring 2W2, which is a power supply line.

### Modified Example Around Chip Mounting Region

Next, a modified example of the semiconductor device PKG1 and the wiring substrate SUB1 described with reference to FIGS. 5 and 6 will be explained. In the case of the semiconductor device PKG1 shown in FIGS. 5 and 6, an embodiment was described in which the gap between conductive patterns 2CP1 is reduced by placing a fixed potential pattern FP between adjacent wirings 2W1 in the chip mounting region RCP. In the modified example described below, an embodiment will be explained in which the gap between conductive patterns 2CP1 is reduced by increasing the wiring width. In the following, the explanation will focus on the differences from the already described semiconductor device PKG1 and wiring substrate SUB1, and the common parts will be omitted in principle.

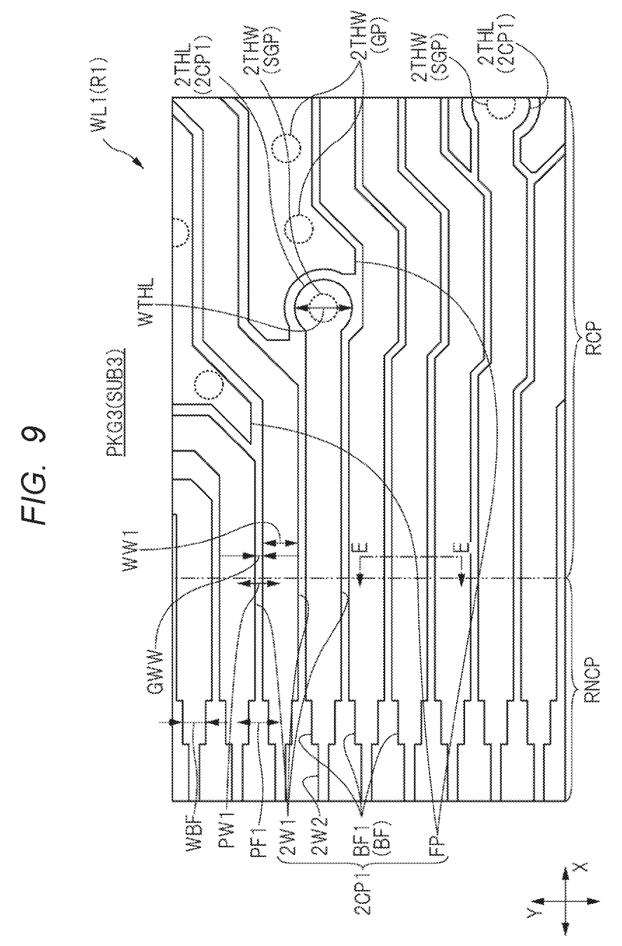

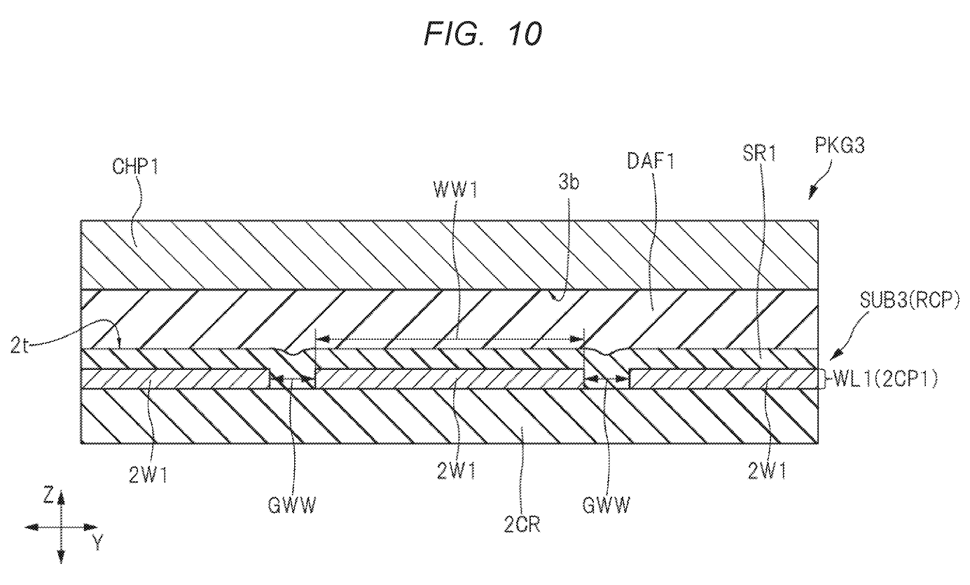

FIG. 9 is an enlarged plan view of a wiring substrate as a modified example of FIG. 5. FIG. 10 is an enlarged cross-sectional view along line E-E of FIG. 9. The wiring substrate SUB3 included in the semiconductor device PKG3 shown in FIGS. 9 and 10 differs from the wiring substrate SUB1 described with reference to FIGS. 5 and 6 in the following points.

In the case of the wiring substrate SUB3, at the position overlapping the outer edge of the chip mounting region RCP, there is no fixed potential pattern FP placed between adjacent wirings 2W1. In other words, the multiple wirings 2W1 are adjacent to each other. This point is similar to the wiring substrate SUB2 shown in FIG. 7.

In the case of the wiring substrate SUB3, the width WW1 of the multiple wirings 2W1 is larger than the distance GWW between the multiple wirings 2W1. This point differs from each of the wiring substrate SUB1 shown in FIG. 5 and the wiring substrate SUB2 shown in FIG. 7.

In the case of the wiring substrate SUB3 included in the semiconductor device PKG3, by widening the width WW1 of the multiple wirings 2W1, the value of the separation distance GWW between adjacent wirings 2W1 is reduced. In this modified example, by reducing the value of the separation distance GWW of the wiring 2W1, the depth of the recess formed on the upper surface 2t of the insulating layer SR1 shown in FIG. 10 can be reduced.

In the example shown in FIG. 9, at the boundary between the chip mounting region RCP and the outer area RNCP of the chip mounting region RCP, there is no fixed potential pattern FP placed between the multiple wirings 2W1. However, as a modified example, there may be cases where a fixed potential pattern FP is placed in a portion of the arrangement of the multiple wirings 2W1. In this case, it is preferable that the relationship between the fixed potential pattern FP and the wiring 2W1 adjacent to the fixed potential pattern FP is as described with reference to FIGS. 5 and 6. As explained using FIG. 6, the depth of the recess formed on the upper surface 2t of the insulating layer SR1 can be reduced.

Also, in the example shown in FIG. 9, the width WW1 of the multiple wirings 2W1 is larger than the width WBF of the bonding finger BF1. The bonding finger BF1 is a part where the wire BW is bonded, as shown in FIG. 3. Therefore, considering the error in the positional accuracy of wire bonding, it is preferable that the width WBF has a certain size. If the arrangement pitch PF1 of the bonding finger BF1 is small, the width WW1 of the wiring 2W1 may be the same as the width WBF of the bonding finger BF1.

On the other hand, the wire BW is not bonded to the wiring 2W1. Also, considering the characteristic impedance in the signal transmission path, designing the width WW1 of the wiring 2W1 to be smaller than the width WBF of the bonding finger BF1 makes impedance matching easier.

However, in this modified example, as shown in FIG. 10, priority is given to reducing the value of the separation distance GWW of the wiring 2W1. As a result, as mentioned above, the width WW1 of the multiple wirings 2W1 is larger than the width WBF of the bonding finger BF1.

However, if the value of the width WW1 of the multiple wirings 2W1 becomes extremely large, the flexibility of the wiring layout decreases. Additionally, if the value of the width WW1 of the multiple wirings 2W1 becomes extremely large, it becomes difficult to match the impedance value of the signal transmission path to the characteristic impedance.

Therefore, it is preferable that the value of the width WW1 of the multiple wirings 2W1 is not extremely large. In this modified example, in the example shown in FIG. 9, one end portion of each of the multiple wirings 2W1 is connected to a through-hole land (via land) 2THL connected to a through-hole wiring (via wiring) 2THW. The width WTHL of the through-hole land 2THL is larger than the width WW1 of the wiring 2W1. In other words, the width WW1 of the wiring 2W1 (the length of the wiring 2W1 in the Y direction) is smaller than the width WTHL of the through-hole land 2THL (the diameter of the through-hole land 2THL).

The semiconductor device PKG3 shown in FIGS. 9 and 10 differs from the semiconductor device PKG1 shown in FIGS. 5 and 6 in the following points. In the semiconductor device PKG3, the arrangement pitch PW1 of each of the multiple wirings 2W1 at the position overlapping the outer edge of the chip mounting region RCP is equal to the arrangement pitch PF1 of each of the multiple bonding fingers BF1 in the Y direction. In other words, each of the multiple wirings 2W1 is arranged with the same arrangement pitch PW1 as the arrangement pitch PF1 of the bonding finger BF1 within the chip mounting region RCP.

Although not shown, as a further modified example for the semiconductor device PKG3, there may be cases where the arrangement pitch PW1 is larger than the arrangement pitch PF1 of each of the multiple bonding fingers BF1. However, in this modified example, the value of the width WW1 of the wiring 2W1 becomes even larger than the example shown in FIG. 9. Therefore, from the viewpoint of suppressing the increase in width WW1, it is preferable that the arrangement pitch PW1 is equal to or less than the arrangement pitch PF1 when there is no fixed potential pattern FP placed between adjacent wirings 2W1.

The semiconductor device PKG3 shown in FIGS. 9 and 10 is similar to the semiconductor device PKG1 shown in FIGS. 5 and 6, except for the differences mentioned above. For example, each of the multiple wirings 2W1 shown in FIG. 9 is part of a transmission path of electrical signals different from each other. Also, for example, the wiring layer WL1 shown in FIG. 9, in a transmission plan view, has the portion overlapping the chip mounting region RCP entirely covered by the insulating layer SR1 (see FIG. 10). Also, as explained with reference to FIG. 3, each of the multiple bonding fingers BF has at least the portion where multiple wires BW are bonded exposed from the insulating layer SR1.

### Method of Manufacturing Semiconductor Device

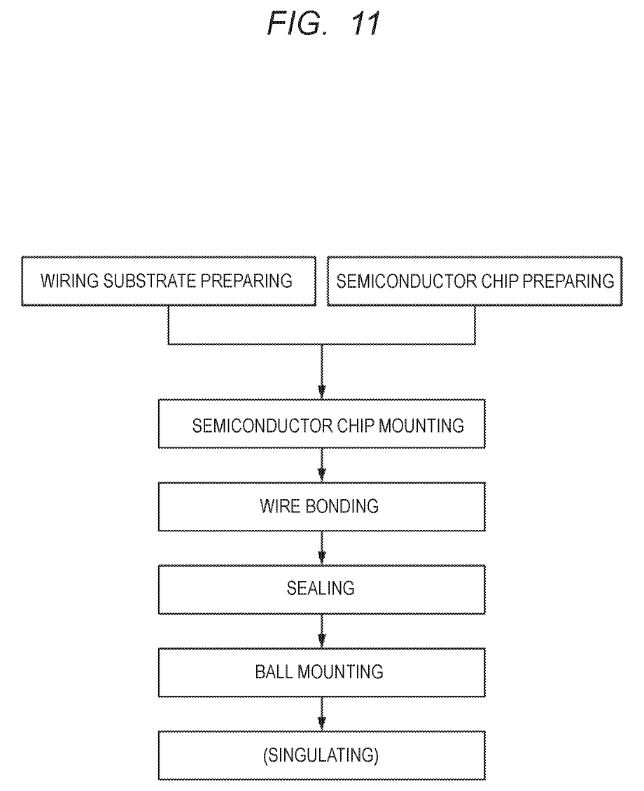

Next, the method of manufacturing a semiconductor device will be described. FIG. 11 is an explanatory diagram showing an example of the manufacturing process of the method of manufacturing a semiconductor device shown in FIG. 1. The method of manufacturing a semiconductor device according to the present embodiment includes each step illustrated in FIG. 11.

### Semiconductor Chip Preparing Step

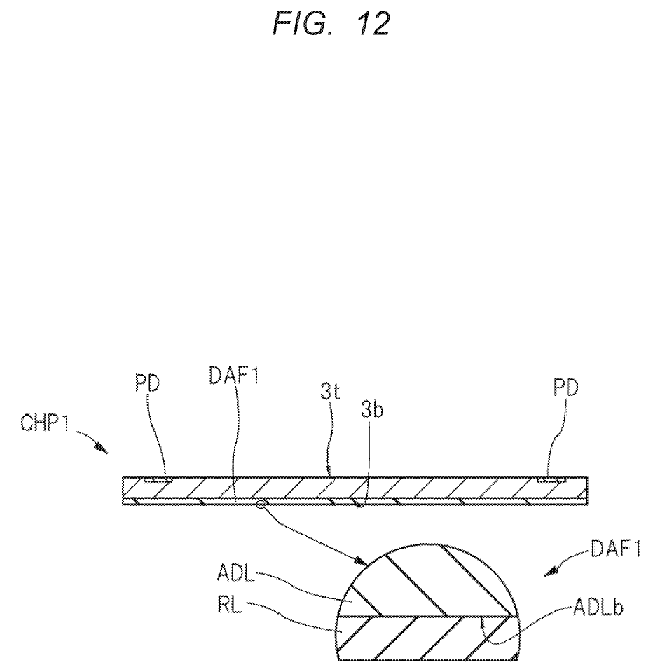

The method of manufacturing a semiconductor device according to the present embodiment includes a semiconductor chip preparation process. In the semiconductor chip preparation process, the semiconductor chip CHP1 shown in FIG. 12 is prepared. FIG. 12 is a cross-sectional view of the semiconductor chip prepared in the semiconductor chip preparation process of FIG. 11. The semiconductor chip CHP1 has an upper surface 3t and a lower surface 3b (see FIG. 4) opposite to the upper surface 3t. On the upper surface 3t of the semiconductor chip CHP1, multiple pads (electrode pads) PD are arranged.

As shown in FIG. 12, the lower surface 3b of the semiconductor chip CHP1 prepared in the semiconductor chip preparation process has an adhesive material DAF1 pre-bonded. The adhesive material DAF1 has an adhesive layer ADL and a release layer RL attached to the lower surface ADLb of the adhesive layer ADL. The release layer RL is a non-adhesive resin layer. The adhesive material DAF1, in addition to having a single-layer structure of the adhesive layer ADL, may also have a three-layer structure with the adhesive layer ADL provided on both the upper and lower surfaces of a non-adhesive layer substrate. In any case, the adhesive layer ADL is attached to the lower surface 3b of the semiconductor chip CHP1. Also, until the semiconductor chip mounting process shown in FIG. 11, it is preferable that the release layer RL is attached to the adhesive layer ADL so that the lower surface ADLb of the adhesive layer ADL is not exposed.

### Wiring Substrate Preparing Step

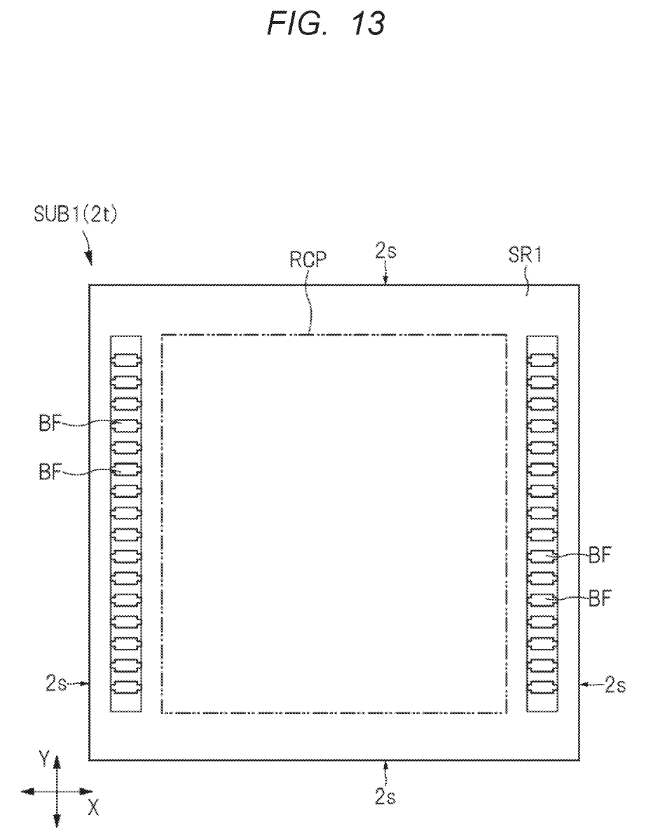

The method of manufacturing a semiconductor device according to the present embodiment includes a wiring substrate preparation process. In the wiring substrate preparation process, the wiring substrate SUB1 shown in FIG. 13 is prepared. FIG. 13 is a plan view showing an example of the wiring substrate prepared in the wiring substrate preparation process shown in FIG. 11.

Hereinafter, an embodiment in which the wiring substrate SUB1 corresponding to one semiconductor device is prepared will be described. However, there are various modified examples of the wiring substrate prepared in this process.

For example, in this process, a so-called multi-device board with multiple device areas (corresponding to the wiring substrate SUB1 in FIG. 13) may be prepared. In this case, as will be explained below, manufacturing efficiency can be improved compared to assembling semiconductor devices PKG1 one by one.

However, when manufacturing using a multi-device board, a singulation process is necessary, as illustrated in parentheses in FIG. 11.

The wiring substrate SUB1 prepared in this process includes an upper surface 2t that includes the chip mounting region RCP, which is the area where the semiconductor chip CHP1 is to be mounted. Of the wiring layer WL1 described with reference to FIGS. 5 and 6, the portion overlapping the chip mounting region RCP is entirely covered by the insulating layer SR1, as shown in FIG. 13. Also, each of the multiple bonding fingers BF has the area where the wire BW (see FIG. 3) is to be bonded exposed from the insulating layer SR1.

### Semiconductor Chip Mounting Step

The method of manufacturing a semiconductor device according to the present embodiment includes a semiconductor chip mounting process. In the semiconductor chip mounting process, as shown in FIGS. 3 and 4, the semiconductor chip CHP1 is mounted on the upper surface 2t of the wiring substrate SUB1.

As already explained, as shown in FIG. 12, the adhesive material DAF1 is pre-bonded to the lower surface 3b of the semiconductor chip CHP1. In the semiconductor chip mounting process, after removing the release layer RL attached to the lower surface ADLb of the adhesive layer ADL of the adhesive material DAF1, the lower surface ADLb is bonded to the upper surface 2t of the wiring substrate SUB1.

As mentioned above, in the chip mounting region RCP of the wiring substrate SUB1 shown in FIG. 13, the entire wiring layer WL1 (see FIG. 5) is covered by the insulating layer SR1. Therefore, as explained with reference to FIG. 8, if many irregularities (depressions or grooves) are formed at a narrow pitch on the upper surface of the insulating layer SR1, the voids (gaps) VD may occur between the adhesive material DAF1 and the upper surface of the insulating layer SR1 (i.e., the upper surface 2t).

In the case of the present embodiment, as explained with reference to FIG. 6, the depth of the depressions formed on the upper surface of the insulating layer SR1 can be reduced. As a result, the entire insulating layer SR1 in the chip mounting region RCP can be adhered to the lower surface of the adhesive material DAF1, i.e., the lower surface ADLb of the adhesive layer ADL shown in FIG. 12.

In the case of the present embodiment, the semiconductor chip CHP1 is mounted such that the lower surface 3b, which is the opposite side of the upper surface 3t where multiple pads PD are arranged, faces the upper surface 2t of the wiring substrate SUB1. Such a mounting method is called a face-up mounting method.

### Wire Bonding Step

The method of manufacturing a semiconductor device according to the present embodiment includes a wire bonding process. In the wire bonding process, as shown in FIGS. 3 and 4, the multiple pads PD of the semiconductor chip CHP1 and the multiple bonding fingers BF of the wiring substrate SUB1 are electrically connected via multiple wires BW.

### Sealing Step

The method of manufacturing a semiconductor device according to the present embodiment includes a sealing process. In the sealing process, as shown in FIG. 4, the semiconductor chip CHP1 and each of the multiple wires BW are sealed by the sealing body MR. The sealing body MR is formed on the upper surface 2t of the wiring substrate SUB1.

The method of forming the sealing body MR is not particularly limited, and various methods can be applied. For example, a method can be exemplified in which a resin with fluidity is molded in a mold for molding and then cured to form the sealing body MR, a so-called transfer molding method.

### Ball Mounting Step

The method of manufacturing a semiconductor device according to the present embodiment includes a ball mount process. In the ball mount process, the multiple lands 2LD of the wiring substrate SUB1 shown in FIG. 4 and the multiple solder balls SB are respectively joined. After placing the solder balls SB on each of the multiple lands 2LD exposed on the lower surface 2b of the wiring substrate SUB1, a reflow process is performed. By heating the solder balls SB to above their melting point and then cooling, the solder balls are joined to the lands 2LD.

Through each of the above processes, the semiconductor device PKG1 shown in FIGS. 1 to 4 is obtained. As mentioned above, when using a multi-device board in the wiring substrate preparation process, a singulation process is carried out by cutting along the dicing area to individualize each of the multiple device areas.

Although the invention made by the present inventor has been specifically described based on the embodiment, the present invention is not limited to the above embodiment, and it is needless to say that various modifications can be made without departing from the gist thereof.

For example, there may be cases where the multiple modified examples described above are combined with each other.

What is claimed is:

1. A semiconductor device comprising:
a semiconductor chip having a first surface on which a plurality of electrode pads is arranged and a second surface opposite the first surface;
a wiring substrate having a third surface including a chip mounting region on which the semiconductor chip is mounted;
a film shaped adhesive material arranged between the second surface of the semiconductor chip and the third surface of the wiring substrate, and attached to each of the semiconductor chip and the wiring substrate; and
a plurality of wires connected to each of the semiconductor chip and the wiring substrate,
wherein the wiring substrate includes:
a first wiring layer in which a plurality of first conductive patterns is formed; and
a first insulating layer covering the first wiring layer and having the third surface,
wherein, in transparent plan view, the plurality of first conductive patterns includes:
a plurality of bonding fingers which is respectively arranged outside the chip mounting region, to which the plurality of wires is respectively bonded, and which is arranged in a first direction;
a plurality of first wirings which is arranged in a first region including a portion of an outer edge of the chip mounting region, and which is respectively connected to a plurality of first bonding fingers of the plurality of bonding fingers; and
a fixed potential pattern arranged between adjacent two first wirings of the plurality of first wirings in the first region, and connected to a transmission path for a fixed potential,
wherein, in transparent plan view, the fixed potential pattern arranged between the adjacent two first wirings and the plurality of first wirings extend so as to across the outer edge of the chip mounting region in a second direction crossing the first direction.

2. The semiconductor device according to claim 1, wherein an arrangement pitch of each of the plurality of first wirings at a position overlapping the portion of the outer edge of the chip mounting region is larger than an arrangement pitch of each of the plurality of first bonding fingers in the first direction.

3. The semiconductor device according to claim 2, wherein, in the position overlapping the portion of the outer edge of the chip mounting region, a distance between each of the adjacent two first wirings and the fixed potential pattern is smaller than a width of the fixed potential pattern.

4. The semiconductor device according to claim 1, wherein each of the plurality of first wirings is a part of a transmission path of electrical signals different from each other.

5. The semiconductor device, according to claim 4, wherein, in the position overlapping the portion of the outer edge of the chip mounting region, a distance between each of the adjacent two first wirings and the fixed potential pattern is smaller than a width of each of the adjacent two first wirings.

6. The semiconductor device according to claim 5, wherein a width of each of the plurality of first wirings is smaller than a width of each of the plurality of first bonding fingers.

7. The semiconductor device, according to claim 4, wherein a ground potential is supplied to the fixed potential pattern.

8. The semiconductor device according to claim 1,
wherein, in transparent plan view, a portion of the first wiring layer overlapping the chip mounting region is entirely covered by the first insulating layer, and
wherein at least a portion, where the plurality of wires is bonded, of each of the plurality of bonding fingers is exposed from the first insulating layer.

9. A semiconductor device comprising:
a semiconductor chip having a first surface on which a plurality of electrode pads is arranged and a second surface opposite the first surface;
a wiring substrate having a third surface including a chip mounting region on which the semiconductor chip is mounted;
a film shaped adhesive material arranged between the second surface of the semiconductor chip and the third surface of the wiring substrate, and attached to each of the semiconductor chip and the wiring substrate; and
a plurality of wires connected to each of the semiconductor chip and the wiring substrate,
wherein the wiring substrate includes:
a first wiring layer in which a plurality of first conductive patterns is formed; and
a first insulating layer covering the first wiring layer and having the third surface,
wherein, in transparent plan view, the plurality of first conductive patterns includes:
a plurality of bonding fingers which is respectively arranged outside the chip mounting region, to which the plurality of wires is respectively bonded, and which is arranged in a first direction; and
a plurality of first wirings which is arranged in a first region including a portion of an outer edge of the chip mounting region, and which is respectively connected to a plurality of first bonding fingers of the plurality of bonding fingers,
wherein the plurality of bonding fingers is arranged in the first direction,
wherein a width of each of the plurality of first wirings is larger than a distance between the plurality of first wirings, and
wherein, in transparent plan view, each of the plurality of first wirings extends so as to across the outer edge of the chip mounting region in a second direction crossing the first direction.

10. The semiconductor device according to claim 9, wherein the width of each of the plurality of first wirings is larger than a width of each of the plurality of first bonding fingers.

11. The semiconductor device according to claim 10,
wherein one end portion of each of the plurality of first wirings is connected to a via land connected to a via wiring, and
wherein a width of the via land in the first direction is larger than the width of each of the plurality of first wirings.

12. The semiconductor device according to claim 9, wherein each of the plurality of first wirings is a part of a transmission path of electrical signals different from each other.

13. The semiconductor device according to claim 9,
wherein, in transparent plan view, a portion of the first wiring layer overlapping the chip mounting region is entirely covered by the first insulating layer, and
wherein at least a portion, where the plurality of wires is bonded, of each of the plurality of bonding fingers is exposed from the first insulating layer.
